(19) United States
(12) Patent Application Publication
(10) Pub. No.: US 2024/0347434 A1
(43) Pub. Date: Oct. 17, 2024

(54) PACKAGE FOR SEMICONDUCTOR

(71) Applicants: NEPES CO., LTD., Samseong-myeon (KR); NEPES LAWEH CORPORATION, Cheongju-si (KR)

(72) Inventors: Jong Heon KIM, Cheongju-si (KR); Young Ho KIM, Cheongju-si (KR); Yun Mook PARK, Cheongju-si (KR); Young Mo LEE, Cheongju-si (KR); Hyung Jin SHIN, Cheongju-si (KR); Kyu Shik KIM, Cheongju-si (KR); Bo Mi LEE, Cheongju-si (KR)

(21) Appl. No.: 18/599,878

(22) Filed: Mar. 8, 2024

(30) Foreign Application Priority Data
Mar. 10, 2023 (KR) 10-2023-0031910
Oct. 18, 2023 (KR) 10-2023-0139878
Oct. 18, 2023 (KR) 10-2023-0139879
Feb. 8, 2024 (KR) 10-2024-0019554

(51) Int. Cl. H01L 23/498; H01L 23/00; H01L 25/10

(52) U.S. Cl. CPC H01L 23/49822; H01L 23/49811; H01L 24/16; H01L 25/105; H01L 2224/16225; H01L 2225/1005

(57) ABSTRACT

A package for semiconductor is disclosed. The semiconductor package according to an aspect of the present invention may include a semiconductor chip; a first insulating layer for embedding the semiconductor chip and protecting the semiconductor chip; a redistribution layer disposed on the first insulating layer; a second insulating layer disposed on the first insulating layer and for embedding the redistribution layer and protecting the redistribution layer; and a conductive pad disposed on the second insulating layer.

### FIELD

The present disclosure relates to a package for semiconductor.

### BACKGROUND

Recently, as the demand for mobile electronic products such as smartphones, tablet PCs, and notebooks has rapidly increased, the size of the electronic products is becoming smaller to make them easier to carry. Accordingly, semiconductor packages used in the electronic products are also required to be thinner, smaller, and lighter, and the development direction is shifted from insert-mounting packages to surface-mounting packages. The surface-mounting packages include Quad Flat Non-lead (QFN), Thin Small Out-line Package (TSOP), Thin Quad Flat Package (TQFP), Ball Grid Array (BGA), and Chip Scale Package (CSP). In particular, the QFN semiconductor packages are attracting great attention because they can significantly reduce the size and weight of semiconductor packages while using lead frames like general semiconductor packages, and can obtain high quality and reliability.

Meanwhile, the QFN semiconductor package has a problem in that the first insulating layer embedding a semiconductor chip is cured, and then the redistribution layer is disposed on one surface of the first insulating layer, and the second insulating layer embedding the redistribution layer is formed, and at this time by forming the redistribution layer and the second insulating layer on the first insulating layer which is already hard, the integration of the first insulating layer and the second insulating layer is not perfect, and the second insulating layer or the redistribution layer is delaminated from the first insulating layer due to repeated thermal deformation occurring at the operating temperature at which the semiconductor chip is actually operated.

### SUMMARY

### Technical Problem

The present disclosure has been made to solve the above problems, and it is an object of the present disclosure to provide a semiconductor package that can improve reliability and productivity through simplification of a semiconductor package structure in a QFN type semiconductor package and prevent a phenomenon in which a second insulating layer or the redistribution layer is delaminated from the first insulating layer.

The technical problems of the present disclosure are not limited to the above-mentioned technical problems, and other technical problems that are not mentioned can be clearly understood by those skilled in the art from the following description.

### Technical Solution

According to an aspect of the present disclosure, there is provided a package for semiconductor including: a semiconductor chip; a first insulating layer for embedding the semiconductor chip and protecting the semiconductor chip; a redistribution layer disposed on the first insulating layer; a second insulating layer disposed on the first insulating layer and for embedding the redistribution layer and protecting the redistribution layer; and a conductive pad disposed on the second insulating layer.

In one embodiment, the first insulating layer and the second insulating layer may form an interface.

In one embodiment, the package for semiconductor may further include a first conductive bump disposed on the semiconductor chip; and a second conductive bump disposed on the redistribution layer.

In one embodiment, a height of the second conductive bump in a vertical direction may be greater than a height of the redistribution layer in a vertical direction.

In one embodiment, the second conductive bump may cover all of an upper surface and a side surface of the redistribution layer.

In one embodiment, the second conductive bump may cover a portion of an upper surface of the redistribution layer and is spaced apart from a side surface of the redistribution layer.

In one embodiment, the redistribution layer may overlap with the semiconductor chip in a vertical direction.

In one embodiment, the package for semiconductor may further include an oxide film disposed on a side surface of the redistribution layer.

In one embodiment, an upper surface of the oxide film may be in contact with the second insulating layer, a lower surface of the oxide film may be in contact with the first insulating layer, and a side surface of the oxide film may be in contact with the redistribution layer.

In one embodiment, a lateral length of the oxide film may be shorter than a lateral length of the redistribution layer.

In one embodiment, an opening is formed in the second insulating layer, may further include an external connection terminal connected to the redistribution layer through the opening of the second insulating layer, wherein a side surface of the redistribution layer may be exposed to the outside of the second insulating layer, and a side surface of the redistribution layer may be located on the same plane as a side surface of the second insulating layer.

In one embodiment, an upper surface of the redistribution layer may be in contact with the first conductive bump, and a lower surface of the redistribution layer may be in contact with the external connection terminal.

In one embodiment, a lateral length of the redistribution layer may be greater than a lateral length of the semiconductor chip.

In one embodiment, the upper surface of the redistribution layer may be located in the same plane as the interface.

In one embodiment, the redistribution layer may overlap with the semiconductor chip in a vertical direction.

In one embodiment, an opening is formed in the second insulating layer, may further include an external connection terminal connected to the redistribution layer through the opening of the second insulating layer; and an oxide film disposed on the side surface of the redistribution layer, wherein a first side surface of the oxide film may be exposed to the outside of the second insulating layer, and the first side surface of the oxide film may be located on the same plane as a side surface of the second insulating layer.

In one embodiment, the modulus of the first insulating layer and the second insulating layer may be different materials.

In one embodiment, the modulus of the second insulating layer may be 60% or less in a room temperature condition and 30% or less in high temperature condition compared to the modulus of the first insulating layer.

In one embodiment, a flexural strength of the second insulating layer may be 60% or less in room temperature condition compared to a flexural strength of the first insulating layer.

In one embodiment, the package for semiconductor may further include a conductive pad exposed on one surface of the second insulating layer and electrically connected to the redistribution layer; and a conductive bump disposed on the semiconductor chip, wherein the other surface of the redistribution layer may be in contact with the conductive bump, and one surface of the redistribution layer is in contact with the conductive pad.

### Advantageous Effects

In the package for semiconductor and the method for manufacturing the semiconductor package, which are exemplary embodiments of the present disclosure, the reliability and productivity of the semiconductor package can be improved through the simplification of the semiconductor package structure. In addition, it is possible to expect the effect of reducing the size of the semiconductor package, improving the performance, and minimizing the delaminating phenomenon.

It should be understood that the effects of the present disclosure are not limited to the above-described effects, and include all effects that can be inferred from the detailed description of the present disclosure or the configuration of the invention described in the claims.

### BRIEF DESCRIPTION OF THE DRAWINGS

FIG. 1 is a cross-sectional view of a package for semiconductor according to a first embodiment of the present disclosure.

FIG. 2 is an enlarged view of a portion P1 of FIG. 1.

FIG. 3 is an enlarged view of a portion corresponding to the P1 of FIG. 1 as a package for semiconductor according to another embodiment of the present disclosure.

FIGS. 4 and 5 are a cross-sectional view and a plan view respectively illustrating a redistribution layer and a second conductive bump.

FIGS. 6 and 7 are a cross-sectional view and a plan view respectively illustrating a redistribution layer and a second conductive bump according to a second embodiment of the present disclosure.

FIG. 8 is a cross-sectional view of a package for semiconductor according to a third embodiment of the present disclosure.

FIG. 9 is a cross-sectional view of a package for semiconductor according to a fourth embodiment of the present disclosure.

FIG. 10 is an enlarged view of a portion P2 of FIG. 9.

FIG. 11 is an enlarged view of a package for semiconductor according to a fifth embodiment of the present disclosure and is an enlarged view of the portion P2 of FIG. 9.

FIG. 12 is a diagram illustrating a package for semiconductor according to a sixth embodiment of the present disclosure.

FIG. 13 is a diagram illustrating physical properties of a first insulating layer and a second insulating layer of the package for semiconductor of FIG. 12.

FIGS. 14 to 23 are cross-sectional views sequentially illustrating a first embodiment of a method of manufacturing a package for semiconductor according to the present disclosure.

FIGS. 24 to 27 are cross-sectional views sequentially illustrating a portion of a second embodiment of a method of manufacturing a package for semiconductor according to the present disclosure.

FIG. 28 is a diagram illustrating a package for semiconductor according to a seventh embodiment of the present disclosure.

### DETAILED DESCRIPTION

Hereinafter, embodiments of the present disclosure will be described in detail with reference to the accompanying drawings so that the person skilled in the art can easily practice the present disclosure. The present disclosure may be implemented in various different forms and is not limited to the embodiments described herein. In order to clearly describe the present disclosure, parts not related to the description are omitted in the drawings, and the same or similar components are denoted by the same reference numerals throughout the specification.

The words and terms used in the specification and claims are not interpreted as limited to ordinary or dictionary meanings, but should be interpreted as meanings and concepts consistent with the technical idea of the present disclosure according to the principle in which the inventor can define the terms and concepts in order to describe their invention in the best way.

Therefore, the configurations described in this specification and illustrated in the drawings correspond to a preferred embodiment of the present disclosure, and are not all representative of the technical idea of the present disclosure, so the corresponding configurations may be various equivalents and modifications to replace them at the time of filing of the present disclosure.

In this specification, it should be understood that the terms such as “include” or “have” are intended to describe the presence of features, numbers, steps, operations, components, parts or combinations thereof described in the specification, but do not preclude the presence or addition of one or more other features, numbers, steps, operations, components, parts or combinations thereof.

It includes not only the case that a component is disposed in the “front”, “rear”. “upper” or “lower” of another component but also the case that another component is disposed in the middle therebetween unless otherwise specified. In addition, it includes not only the case that a component is “connected” to another component, unless otherwise specified, not only the case that the component is directly connected to each other but also the case that the component is indirectly connected to each other.

Hereinafter, the package for semiconductor according to a first embodiment of the present disclosure will be described with reference to the drawings.

The semiconductor package 10a according to the first embodiment of the present disclosure may include a semiconductor chip 100 having a chip pad 102, a pair of dummy chips 110a and 110b disposed laterally to be spaced apart from each other with the semiconductor chip 100 interposed therebetween, a first conductive bump 120 disposed on the chip pad 102 of the semiconductor chip 100, and a first insulating layer 132 for embedding the semiconductor chip and the pair of dummy chips 110a and 110b and surrounding sidewalls of the first conductive bump 120. In addition, the semiconductor package 10a may further include, a redistribution layer 140 disposed on the first conductive bump 120 and the first insulating layer 132, a second conductive bump 150 disposed on the redistribution layer 140, a second insulating layer 134 disposed on the first insulating layer 132 and for embedding the redistribution layer 140 and the second conductive bump 150, and a conductive pad 160 disposed on the second conductive bump 150. According to an embodiment, the first conductive bump 120 may be referred to as a stud, and the second conductive bump 150 may be referred to as a stump. Of course, the dummy chips 110a and 110b may be omitted as necessary.

In the present specification, a direction in which the pair of dummy chips 110a and 110b are spaced apart from each other with the semiconductor chip 100 interposed therebetween may be defined as a first horizontal direction (X direction). In addition, a direction orthogonal to the first horizontal direction (X direction) may be defined as a second horizontal direction (Y direction). In addition, a direction orthogonal to the first horizontal direction (X direction) and the second horizontal direction (Y direction) and simultaneously orthogonal to the upper surface of the semiconductor chip 100 may be defined as a vertical direction (Z direction).

A plurality of individual devices of various kinds may be formed in the semiconductor chip 100. For example, the plurality of individual devices may include various microelectronic devices, for example, metal-oxide semiconductor field effect transistors (MOSFET), such as complementary metal-oxide-semiconductor transistors (CMOS), image sensors, such as system large scale integration (LSI), CMOS imaging sensor (CIS), micro-electro-mechanical systems (MEMS), active devices, and passive devices.

In exemplary embodiments, the semiconductor chip 100 may be, for example, a memory semiconductor chip 110. The memory semiconductor chip 100 may be, for example, a volatile memory semiconductor chip 100 such as Dynamic Random Access Memory (DRAM) or Static Random Access Memory (SRAM), or a non-volatile memory semiconductor chip 100 such as Phase-change Random Access Memory (PRAM), Magneto resistive Random Access Memory (MRAM), Ferroelectric Random Access Memory (FeRAM), or Resistive Random Access Memory (RRAM). Alternatively, in exemplary embodiments, the semiconductor chip 100 may be a logic chip. For example, the semiconductor chip 110 may be a Central Processing Unit (CPU), Micro Processor Unit (MPU), Graphic Processor Unit (GPU), or Application Processor (AP).

The pair of dummy chips 110a and 110b may be disposed to be spaced apart in the first horizontal direction (X direction) with the semiconductor chip 100 interposed therebetween, thereby reducing warping of the semiconductor package 10a. In order to reduce the warpage, the pair of dummy chips 110a and 110b may include a material having a relatively low modulus. For example, the dummy chips 110a and 110b may be formed of a material having a modulus lower than that of the first insulating layer 132 or the second insulating layer 134. For example, the dummy chips 110a and 110b may be bare wafers, and the first insulating layer 132 and the second insulating layer 134 may include EMC.

In this embodiment, the pair of dummy chips 110a and 110b may have the same vertical height as the semiconductor chip 100 in the vertical direction (Z direction). However, it is not necessarily limited to the above, and the pair of dummy chips 110a and 110b may each have a lower vertical height than the semiconductor chip 100.

According to this embodiment, the semiconductor chip 100 may include a chip pad 102. The chip pad 102 may be electrically connected to the individual devices formed in the semiconductor chip 100. In addition, although not specifically shown, the semiconductor chip 100 may include a passivation film covering the upper surface thereof.

The second insulating layer 134 may be stacked on the first insulating layer 132 while being in contact with the upper surface of the first insulating layer 132. The first insulating layer 132 and the second insulating layer 134 may be formed from a material film made of an organic compound. For example, the first insulating layer 132 and the second insulating layer 134 may include an insulating polymer. For example, the first insulating layer 132 and the second insulating layer 134 may include a photo imagable dielectric (PID), an Ajinomoto Build-up Film (ABF), or a photosensitive polyimide (PSPI). The first insulating layer 132 and the second insulating layer 134 may be referred to as a molding layer or an encapsulation layer surrounding the chip.

In exemplary embodiments, the first insulating layer 132 and the second insulating layer 134 may each include a non-photosensitive material or a photosensitive material.

In exemplary embodiments, a thickness of the first insulating layer 132 may be greater than a thickness of the second insulating layer 134. For example, when the thickness of the first insulating layer 132 is approximately 40 micrometers to 400 micrometers, the thickness of the second insulating layer 134 may be approximately 20 micrometers to 100 micrometers.

In exemplary embodiments, the surface roughness of the upper surface of the first insulating layer 132 may be greater than the surface roughness of the lower surface of the first insulating layer 132 (i.e., the surface of the first insulating layer 132 facing the lower surface of the semiconductor chip). In addition, the surface roughness of the upper surface of the first insulating layer 132 may be greater than the surface roughness of the lower surface of the second insulating layer 134 (i.e., the surface of the second insulating layer 134 facing the upper surface of the first insulating layer 132). By forming the upper surface of the first insulating layer 132 to have a relatively large surface roughness, the adhesion between the first insulating layer 132 and the redistribution layer 140 in contact with the upper surface of the first insulating layer 132 may be improved. In addition, the first insulating layer 132 and the second insulating layer 134 may form an interface.

The first conductive bump 120 may be disposed on the chip pad 102 of the semiconductor chip 100, and may be electrically and physically connected to the chip pad 102 of the semiconductor chip 100. The first conductive bump 120 may be formed before the first insulating layer 132. That is, before the first insulating layer 132 is formed by a molding process, the first conductive bump 120 may be formed on the chip pad 102 through a plating process. Therefore, the first conductive bump 120 is not a tapered shape in which the diameter is narrower as it becomes closer to the semiconductor chip 100, but may have a cylindrical shape in which diameter is constant even as it becomes closer to the semiconductor chip 100. That is, the first conductive bump 120 may have a pillar shape. The horizontal width of the first conductive bump 120 (i.e., the width of the first conductive bump 120 along the direction (X direction and/or Y direction) parallel to the upper surface of the semiconductor chip 100) may be substantially uniform. The first conductive bump 120 may be formed to completely overlap with the chip pad 102 in the vertical direction (Z direction).

The first conductive bump 120 may include a conductive material. For example, the first conductive bump 120 may include copper (Cu), aluminum (Al), tungsten (W), titanium (Ti), palladium (Pd), gold (Au), cobalt (Co), nickel (Ni), or a combination thereof.

According to this embodiment, the redistribution layer 140 may be disposed on the upper surface of the first insulating layer 132, and may have a predetermined thickness along the upper surface of the first insulating layer 132. In this case, the length of the redistribution layer 140 in the first horizontal direction (X direction) may be long than the length of the semiconductor chip 100 in the first horizontal direction (X direction). The redistribution layer 140 may be disposed on the semiconductor chip 100 to completely cover the semiconductor chip 100. The redistribution layer 140 may be disposed to completely cover the semiconductor chip 100 and one of the pair of dummy chips 110a and 110b. That is, the redistribution layer 140 may overlap with the semiconductor chip 100 in the vertical direction (Z direction) and overlap with at least one of the first dummy chip 110a or the second dummy chip 110b in the vertical direction (Z direction). However, the shape of the redistribution layer 140 is not limited to the above description, and the redistribution layer 140 may have more various shapes and patterns.

A portion of the side surface 140s of the redistribution layer 140 may be exposed to the outside of the second insulating layer 134, and a portion of the side surface 140s of the redistribution layer 140 may be located on the same plane as the side surface 134s of the second insulating layer 134. In addition, a portion of the side surface 140s of the redistribution layer 140 may be located on the same plane as the side surface 132s of the first insulating layer 132. In other words, the entire side surface 140s of the redistribution layer 140 may not be exposed, but a portion of the side surface 140s may be exposed.

The redistribution layer 140 may include a conductive material. For example, the redistribution layer 140 may include copper (Cu), aluminum (Al), tungsten (W), titanium (Ti), palladium (Pd), gold (Au), cobalt (Co), nickel (Ni), or a combination thereof.

According to this embodiment, the second conductive bump 150 may be located on the redistribution layer 140. In this case, the second conductive bump 150 may not overlap with the first conductive bump 120 in the vertical direction. The height of the second conductive bump 150 in the vertical direction (Z direction) may be greater than the height of the redistribution layer 140 in the vertical direction (Z direction). According to an embodiment, the second conductive bump 150 may electrically connect the redistribution layer 140 and the conductive pad 160.

According to this embodiment, the conductive pad 160 may be disposed on the second insulating layer 134. The conductive pad 160 may be disposed to overlap with the second conductive bump 150.

According to this embodiment, the semiconductor package 10a may further include a cover layer 170 surrounding the conductive pad 160. For example, the cover layer 170 may be formed using an electroless plating method or a sputtering method to cover at least a portion of the surface of the conductive pad 160.

In exemplary embodiments, the cover layer 170 may be formed to entirely cover the surface of the conductive pad 160. That is, the cover layer 170 may cover the upper surface and the sidewall of the conductive pad 160. Alternatively, in other exemplary embodiments, the cover layer 170 may be formed to cover only a portion of the surface of the conductive pad 160. For example, the cover layer 170 may be formed only on the sidewall of the conductive pad 160.

In exemplary embodiments, the cover layer 170 may include a metal material with excellent wettability. For example, the cover layer 170 may include gold (Au), palladium (Pd), nickel (Ni), copper (Cu), solder, or a combination thereof.

Alternatively, in other exemplary embodiments, a conductive wire may be attached to the cover layer 170. The conductive wire may extend between an external substrate and the cover layer 170 and electrically connect the external substrate and the cover layer 170.

The cover layer 170 may be a metal film formed in a thin thickness on the surface of the conductive pad 160. In exemplary embodiments, the thickness of the cover layer 170 may be 0.001 μm or more, 0.005 μm or more, 0.01 μm or more, 0.05 μm or more, or 0.1 μm or more. When the thickness of the cover layer 170 is smaller than 0.001 μm, the wettability of the cover layer 170 may be lowered.

The width w1 of the second conductive bump 150 in the first horizontal direction (X direction) may be shorter than the width w2 of the conductive pad 160 in the second horizontal direction (Y direction).

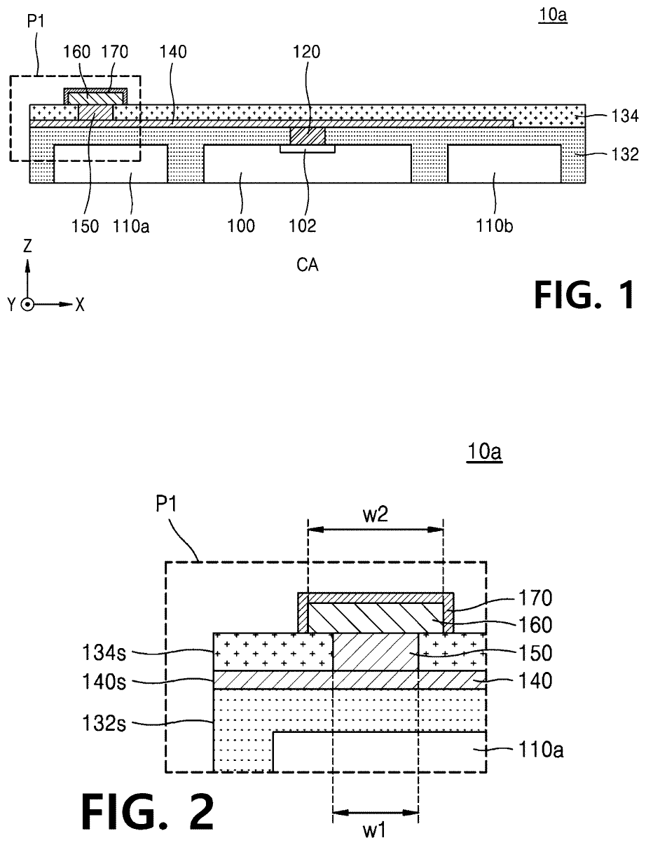

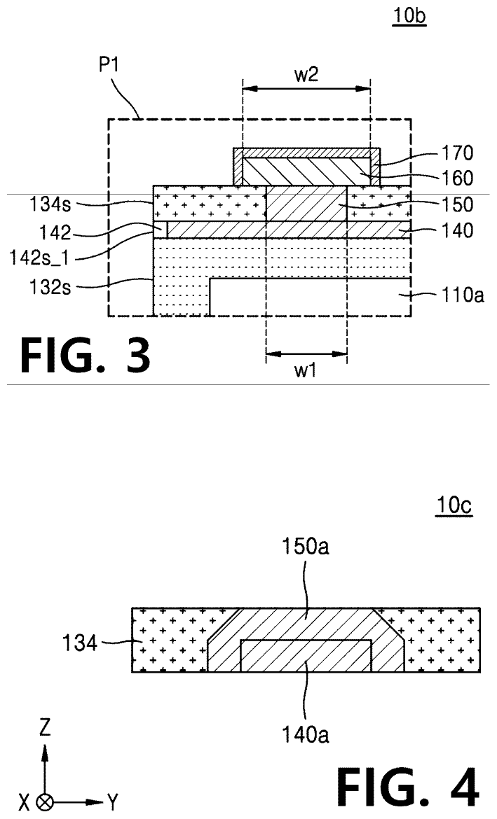

FIG. 3 is an enlarged view of a portion corresponding to P1 of FIG. 1 as a package for semiconductor according to another embodiment of the present disclosure. Referring to FIG. 3, the semiconductor package 10b is substantially the same as or similar to the semiconductor package 10a shown in FIGS. 1 and 2, except that it further includes a metal oxide film 142 disposed on the side surface of the redistribution layer 140. Therefore, the description of the components already mentioned with reference to FIGS. 1 and 2 will be omitted or simplified.

According to this embodiment, the semiconductor package 10b may further include a metal oxide film 142 disposed on the side surface of the redistribution layer 140. The metal oxide film 142 may be formed by a reaction with external air of a portion of the redistribution layer 140 exposed to the outside of the second insulating layer 134.

The metal oxide film 142 may have a first side surface 142s_1 facing the outside of the second insulating layer 134 and a second side surface 142s_2 opposite to the first side surface 142s_1. The first side surface 142s_1 may be exposed to the outside of the second insulating layer 134, and the first side surface 142s_1 may be located on the same plane as the side surface of the second insulating layer 134. An upper surface of the metal oxide film 142 may be in contact with the second insulating layer 134, and a lower surface of the metal oxide film 142 may be in contact with the first insulating layer 132. In addition, the second side surface 142s_2, which is opposite to the first side surface 142s_1 of the metal oxide film 142, may be in contact with the redistribution layer 140.

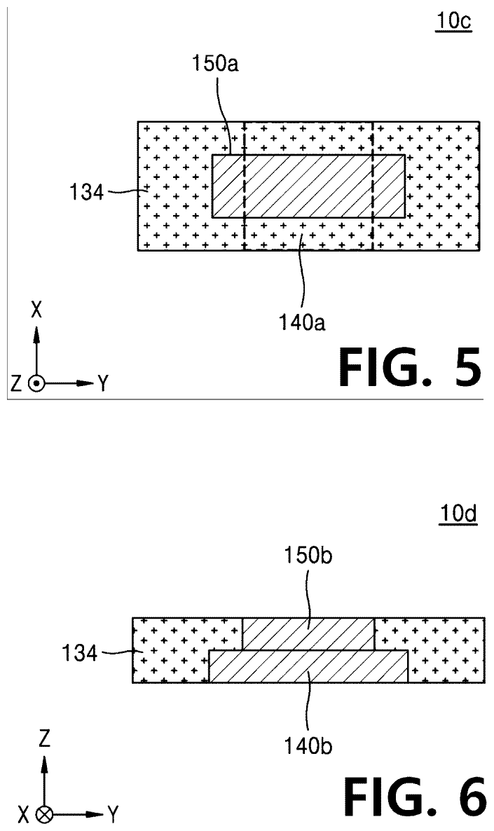

FIGS. 4 and 5 are a cross-sectional view and a plan view respectively illustrating a redistribution layer and a second conductive bump. The redistribution layer 140a and the second conductive bump 150a, illustrated in FIGS. 4 and 5 may be an example of the redistribution layer 140 and the second conductive bump 150 illustrated in FIG. 1.

Referring to FIGS. 4 and 5, the second conductive bump 150a according to an embodiment may cover at least a portion of an upper surface and a side surface of the redistribution layer 140a. The redistribution layer 140a may extend long in the first horizontal direction (X direction), and the second conductive bump 150a may be disposed on the redistribution layer 140a to cover the upper surface and the side surface of the redistribution layer 140a. The redistribution layer 140a may extend in the first horizontal direction (X direction) with a predetermined thickness. The width of the redistribution layer 140a in the second horizontal direction (Y direction) may be narrower than the width of the second conductive bump 150a in the second horizontal direction (Y direction). The second conductive bump 150a may surround the redistribution layer 140a in the form of ‘C’. In addition, as illustrated in FIG. 5, the width of the second conductive bump 150a in the first horizontal direction (X direction) may be smaller than the width of the redistribution layer 140a in the first horizontal direction (X direction). However, the width of the second conductive bump 150a in the second horizontal direction (Y direction) may be larger than the width of the redistribution layer 140a in the second horizontal direction (Y direction). In this case, the thickness of the redistribution layer 140a in the vertical direction (Z direction) and the thickness of the first conductive bump 150a in the vertical direction (Z direction) may be the same. An area for forming the first conductive bump 150a is located on one side of the redistribution layer 140a, and the first conductive bump 150a may be formed on this area. In this case, the redistribution layer 140a may be formed with the same thickness, and the first conductive bump 150a may be formed thereon.

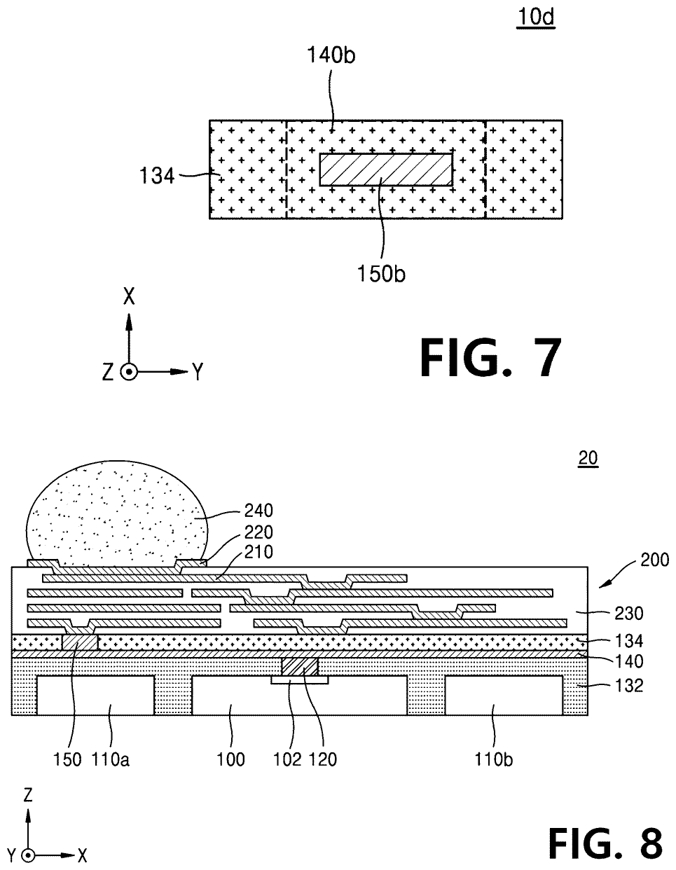

FIGS. 6 and 7 are a cross-sectional view and a plan view respectively illustrating a redistribution layer and a second conductive bump according to a second embodiment of the present disclosure. The redistribution layer 140b and the second conductive bump 150b, illustrated in FIGS. 6 and 7 may be an example of the redistribution layer 140 and the second conductive bump 150 illustrated in FIG. 1.

Referring to FIGS. 6 and 7, the second conductive bump 150b according to this embodiment may cover a portion of an upper surface of the redistribution layer 140b, and may not be in contact with a side surface of the redistribution layer 140b. The length of the second conductive bump 150b in the second horizontal direction (Y direction) may be shorter than the length of the redistribution layer 140b in the second horizontal direction (Y direction). In addition, the length of the second conductive bump 150b in the first horizontal direction (X direction) may also be shorter than the length of the redistribution layer 140b in the first horizontal direction (X direction). That is, the second conductive bump 150b may be disposed to completely overlap the redistribution layer 140b. In addition, as illustrated in FIG. 7, the width of the second conductive bump 150b in the first horizontal direction (X direction) and the width in the second horizontal direction (Y direction) may be smaller than the width of the redistribution layer 140b in the second horizontal direction (Y direction). In this case, the thickness of the redistribution layer 140b in the vertical direction (Z direction) and the thickness of the second conductive bump 150b in the vertical direction (Z direction) may be the same. An area for forming the second conductive bump 150b is located on one side of the redistribution layer 140b, and the second conductive bump 150b may be formed on this area. In this case, an area on one side of the redistribution layer 140b may be thick, and the second conductive bump 150b may be formed on this region.

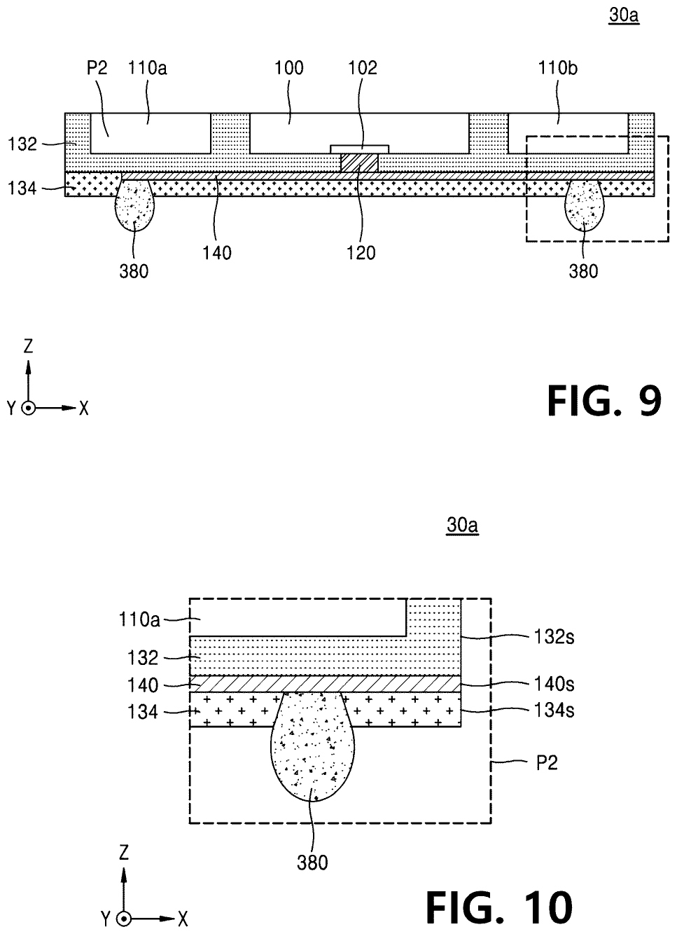

FIGS. 8 and 9 are cross-sectional views of a package for semiconductor according to the third and fourth embodiments of the present disclosure, respectively, and FIG. 10 is an enlarged view of the portion P2 of FIG. 9.

Referring to FIG. 8, the semiconductor package 20 illustrated in FIG. 8 is substantially the same as or similar to the semiconductor package 10a illustrated in FIGS. 1 and 2, except that the semiconductor package 20 further includes a redistribution structure 200 disposed on the second insulating layer 134. Therefore, descriptions of the components already mentioned with reference to FIGS. 1 and 2 will be omitted or simplified.

According to this embodiment, the semiconductor package 20 may further include the redistribution structure 200 disposed on the second insulating layer 134. The redistribution structure 200 may be provided on the upper surface of the second insulating layer 134. The redistribution structure 200 may include a conductive pattern 210, an external conductive pad 220, a passivation film 230, and an external connection terminal 240.

The conductive pattern 210 may include a line pattern extending in the first horizontal (X direction) or the second horizontal (Y direction) inside the passivation film 230 and a via pattern extending in the vertical direction (Z direction) from the line pattern. The via pattern may be connected to the second conductive bump 150. The conductive pattern 210 may provide an electrical passage between the second conductive bump 150 and the external conductive pad 220. For example, the external conductive pad 220 may be an Under Bump Metallization (UBM) pad. The external conductive pad 220 and the conductive pattern 210 may include, for example, a conductive material including copper (Cu), aluminum (Al), silver (Ag), gold (Au), tungsten (W), titanium (Ti), or a combination thereof.

The passivation film 230 may serve to protect other structures underneath or inside the passivation film 230 from external shock or moisture. For example, the passivation film 230 may include an oxide, a nitride, a polymer, or a combination thereof. In some embodiments, the passivation film 230 may include silicon oxide, silicon nitride, or a combination thereof.

According to this embodiment, the passivation film 230 may be formed on the second insulating layer 134 and the passivation film 230 may be exposed to form a via hole. A seed material layer including a Ti/Cu alloy may be formed in the via hole. However, the material including the seed material layer is not limited to the above. Thereafter, the conductive pattern 210 may be formed by filling the via hole on which the seed material layer is deposited with a conductive material using a photoresist patterning process and a plating process. This process may be repeatedly formed to form the redistribution structure 200.

However, if necessary, the redistribution structure 200 may be formed directly on the first insulating layer 132 without forming the second insulating layer 134 or the redistribution layer 140.

The external connection terminal 240 may be located on the upper surface of the external conductive pad 220. The external connection terminal 240 may include, for example, a conductive material including tin (Sn), lead (Pb), silver (Ag), copper (Cu), or a combination thereof. The external connection terminal 240 may be formed using, for example, a solder ball. The external connection terminal 240 may connect the semiconductor package 20 to a circuit board, another semiconductor package, an interposer, or a combination thereof.

Referring to FIGS. 9 and 10, the semiconductor package 30a according to the fourth embodiment of the present disclosure is substantially the same or similar, except that the semiconductor package 30a does not include the second conductive bump 150 and the conductive pad 160, but instead includes an external connection terminal 380 bonded to the redistribution layer 140, as compared to the semiconductor package 10a illustrated in FIGS. 1 and 2. Therefore, descriptions of the components already mentioned with reference to FIGS. 1 and 2 will be omitted or simplified.

The external connection terminal 380 may be bonded to the lower surface of the redistribution layer 140 connected to the first conductive bump 120. The external connection terminal 380 may be attached to the redistribution layer 140 through an opening formed in the second insulating layer 134. The external connection terminal 380 may include, for example, a conductive material including tin (Sn), lead (Pb), silver (Ag), copper (Cu), or a combination thereof. The external connection terminal 240 may be formed using, for example, a solder ball. The external connection terminal 240 may connect the semiconductor package 30a to a circuit board, another semiconductor package, an interposer, or a combination thereof.

The side surface 140s of the redistribution layer 140 may be exposed to the outside of the second insulating layer 134, and the side surface 140s of the redistribution layer 140 may be located on the same plane as the side surface 134s of the second insulating layer 134. In addition, the side surface 140s of the redistribution layer 140 may be located on the same plane as the side surface 132s of the first insulating layer 132.

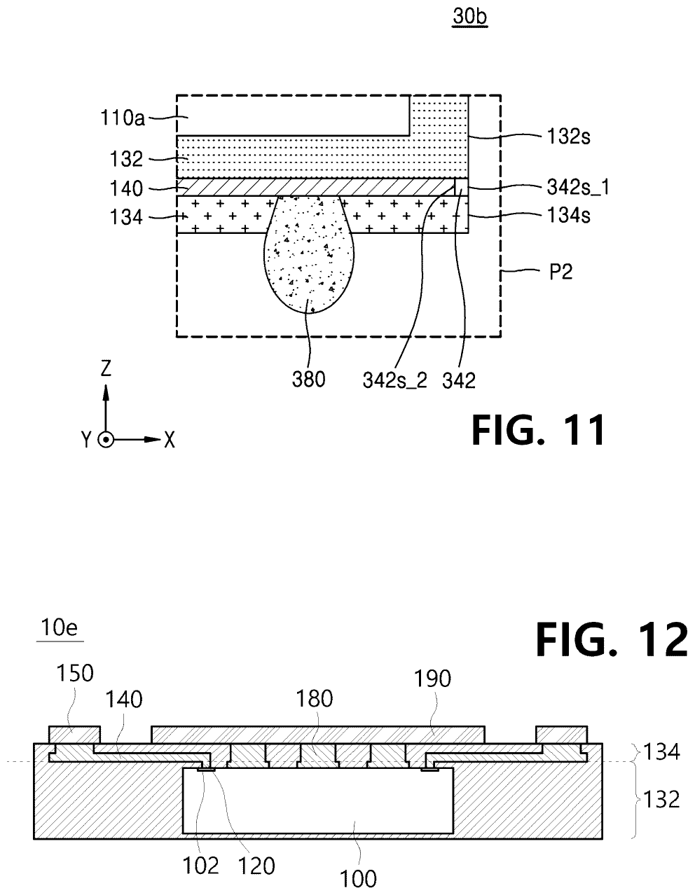

FIG. 11. is an enlarged view of a portion corresponding to the P2 in FIG. 9 as a package for semiconductor according to the fifth embodiment of the present disclosure.

Referring to FIG. 11, the semiconductor package 30b according to this embodiment is substantially the same or similar to the semiconductor package 30b illustrated in FIG. 10, except that the semiconductor package 30b further includes an oxide film 342 disposed on the side surface of the redistribution layer 140. Therefore, descriptions of the components already mentioned with reference to FIG. 10 will be omitted or simplified.

According to this embodiment, the semiconductor package 30b may further include an oxide film 342 disposed on the side surface of the redistribution layer 140. The oxide film 342 may be formed by a reaction of a portion of the redistribution layer 140 exposed to the outside of the second insulating layer 134 with external air.

The oxide film 342 may have a first side surface 342s_1 facing the outside of the second insulating layer 134 and a second side surface 342s_2 opposite to the first side surface 342s_1. A portion of the first side surface 342s_1 may be exposed to the outside of the second insulating layer 134, and a portion of the first side surface 342s_1 may be located on the same plane as the side surface of the second insulating layer 134. An upper surface of the oxide film 342 may be in contact with the second insulating layer 134, and a lower surface of the oxide film 342 may be in contact with the first insulating layer 132. In addition, a portion of the second side surface 342s_2, which is opposite to the first side surface 342s_1 of the oxide film 342 may be in contact with the redistribution layer 140.

FIG. 12 is a view illustrating a semiconductor package 10e according to the sixth embodiment of the present disclosure.

As illustrated in FIG. 12, the semiconductor package 10e according to this embodiment may include a semiconductor chip 100 having a chip pad 102 formed on one surface thereof, a first conductive bump 120 protruding to one side on the chip pad 102 of the semiconductor chip 100, a first insulating layer 132 embedding the semiconductor chip 100 and the first conductive bump 120, a redistribution layer 140 disposed on one surface of the first insulating layer 132 and extending laterally from the first conductive bump 120, a second conductive bump 180, a second insulating layer 134 disposed on the first insulating layer 132 and embedding the redistribution layer 140 and the second conductive bump 180, and a conductive pad 190 disposed on the second conductive bump 180.

this case, the chip pad 102 may be formed in an outer area on one surface of the semiconductor chip 100.

In addition, a heat conduction stump 180 may be formed to protrude from the central area on one surface of the semiconductor chip 100. The heat conduction stump 180 may be disposed so that one end thereof may be exposed on one surface of the second insulating layer 134, and the other end thereof may be placed in contact with one surface of the semiconductor chip 100. In addition, a heat dissipation pad 190 in contact with the heat conduction stump 180 and exposed to the outside may be disposed on one surface of the second insulating layer 134 where the heat conduction stump 180 is exposed. Therefore, heat generated during the operation of the semiconductor chip 100 may be dissipated through the heat conduction stump 180 and the heat dissipation pad 190. Of course, the heat conduction stump 180 and the heat dissipation pad 190 may be omitted as necessary.

In addition, in the above embodiment, a pair of dummy chips 110a and 110b are disposed in the first insulating layer 132, but in the semiconductor package 10e according to this embodiment, the dummy chips 110a and 110b are omitted as examples. However, the present disclosure is not limited thereto, and dummy chips may be disposed as necessary.

Meanwhile, the modulus of the first insulating layer 132 and the second insulating layer 134 may be different.

When the semiconductor package is manufactured, after the first insulating layer 132 is cured, the redistribution layer 140 is disposed on one surface of the first insulating layer 132, and the second insulating layer 134 embedding the redistribution layer 140 is formed.

In addition, the temperature of the semiconductor package may vary during operation and when not in operation. That is, when the semiconductor package is in operation, it may be heated to a high temperature of 200 degrees Celsius or more, and when the semiconductor package is not in operation, it may be cooled to a room temperature of about 25 degrees Celsius. In addition, due to repeated heating and cooling, a delamination phenomenon in which the redistribution layer 140 or the second insulating layer 134 is peeled off by repeated thermal expansion and thermal shrinkage of the first insulating layer 132 and the second insulating layer 134 may occur.

In order to prevent this, the first insulating layer 132 and the second insulating layer 134 may have different modulus, and particularly, the modulus of the second insulating layer 134 may be lower than the modulus of the first insulating layer 132.

In addition, the modulus may be a flexural modulus.

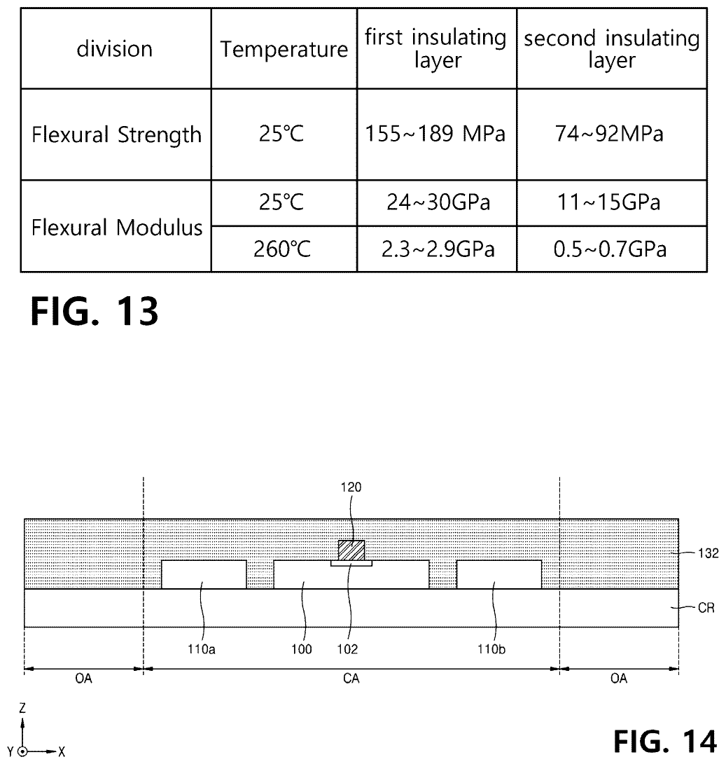

FIG. 13 is a diagram illustrating physical properties of the first insulating layer 132 and the second insulating layer 134.

As an example, the flexural modulus of the second insulating layer 134 may be 60% or less at room temperature conditions compared to the flexural modulus of the first insulating layer 132.

In addition, the modulus of the second insulating layer 134 may be 30% or less in the high temperature conditions compared to the modulus of the first insulating layer 132.

In this case, the room temperature conditions may be 10 to 30 degrees Celsius, and the high temperature conditions may be the temperature at which the semiconductor chip is operated and may be 200 to 280 degrees Celsius.

As an example, the flexural modulus of the first insulating layer 132 may be 24 to 30 GPa at room temperature of 25 degrees Celsius, and 2.3 to 2.9 GPa at a high temperature of 260 degrees Celsius.

In addition, the flexural modulus of the second insulating layer 134 may be 11 to 15 GPa at room temperature of 25 degrees Celsius, and 0.5 to 0.7 GPa at high temperature of 260 degrees Celsius.

The difference between the modulus of the second insulating layer 134 at room temperature condition and the high temperature condition may be 60% or less compared to the difference between the modulus of the first insulating layer 132 at room temperature condition and the high temperature condition.

That is, as illustrated in FIG. 13, the difference between the modulus of the first insulating layer 132 at room temperature condition and the high temperature condition according to this embodiment may be approximately 24 GPa, and the difference between the modulus of the second insulating layer 134 at room temperature condition and the high temperature condition may be 12 GPa, and may correspond to approximately 50.8%.

In addition, the flexural strength of the second insulating layer 134 may be 60% or less at room temperature condition compared to the flexural strength of the first insulating layer 132.

In addition, the adhesion force of the second insulating layer 134 to copper may be stronger than that of the first insulating layer 132 to copper. As an example, the adhesion force of the second insulating layer 134 to copper may be 0.93 kgf, and the adhesion force of the first insulating layer 132 to copper may be 0.50 kgf, and the adhesion force of the second insulating layer 134 to copper may be 180% or more of the adhesion force of the first insulating layer to copper. In this case, the redistribution layer 140 may be formed of a copper material.

Therefore, since the modulus of the second insulating layer 134 is lower than the modulus of the first insulating layer 132, when the first insulating layer 132 is thermally expanded and thermally contracted, the force resisting the deformation of the second insulating layer 134 decreases, and the delamination of the second insulating layer 134 and the first insulating layer 132 is prevented, and the adhesion force of the second insulating layer 134 and the redistribution layer 140 made of the material including copper is stronger than the adhesion force of the first insulating layer 132 and the redistribution layer 140, and the delamination of the redistribution layer 140 and the second insulating layer 134 may not occur.

Therefore, as a result, the delamination of the second insulating layer 134 and the redistribution layer 140 from the first insulating layer 132 may be prevented, and the durability of the semiconductor package may be improved.

FIGS. 14 to 23 are diagrams sequentially illustrating the first embodiment of the method of manufacturing a semiconductor package according to the present disclosure.

Referring to FIG. 14, the method for manufacturing a semiconductor package according to this embodiment may include disposing a semiconductor chip 100 provided with a chip pad 102 and a pair of dummy chips 110a and 110b spaced apart in a first horizontal direction (X direction) with the semiconductor chip 100 interposed therebetween on a carrier substrate CR. In this case, the area on the carrier substrate CR where the semiconductor chip 100 and the pair of dummy chips 110a and 110b are disposed may be defined as a center area CA, and the areas surrounding the center area CA may be defined as an outer area OA. According to an embodiment, the outer area OA may include a sawing line divided by package unit or a sawing line divided by block unit within the package.

According to this embodiment, the method for manufacturing a semiconductor package according to an embodiment of the present disclosure may include disposing the semiconductor chip 100 and the pair of dummy chips 110a and 110b on the carrier substrate CR. In this case, a first conductive bump 120 including a conductive material may be disposed on the chip pad 102. After attaching the semiconductor chip 100 and the pair of dummy chips 110a and 110b on the carrier substrate CR, a first insulating layer 132 may be formed to embed the semiconductor chip 100, the pair of dummy chips 110a and 110b, and the first conductive bump 120.

Of course, the dummy chips 110a and 110b may be omitted if necessary.

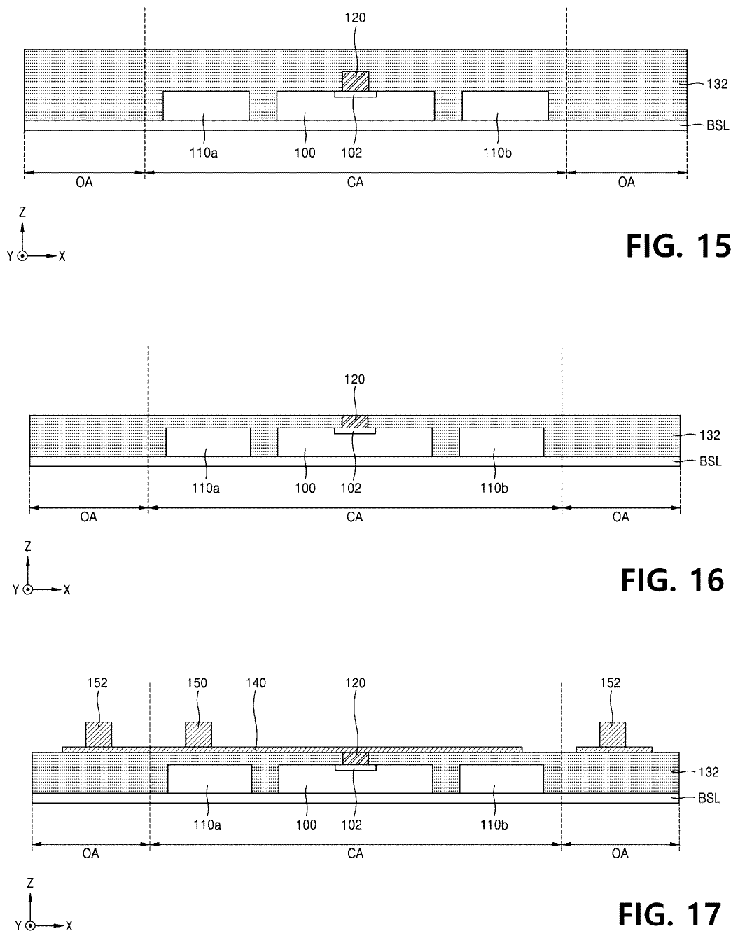

Referring to FIG. 15, the method for manufacturing a semiconductor package according to this embodiment may include attaching a backside insulating film (BSL) on the lower surface of the semiconductor chip 100, the pair of dummy chips 110a and 110b, and the first insulating layer 132 after removing the carrier substrate CR.

Referring to FIG. 16, the method for manufacturing a semiconductor package according to this embodiment may include removing a portion of the first insulating layer 132 and a portion of the first conductive bump 120 by grinding them. The upper surface of the first conductive bump 120 may be exposed to the outside of the first insulating layer 132 through the grinding process.

Referring to FIG. 17, the method for manufacturing a semiconductor package according to this embodiment may include forming a redistribution layer 140 and a plurality of first conductive bumps 120 on an upper surface of the grounded first insulating layer 132. The plurality of first conductive bumps 120 may include a first conductive bump 120 disposed in the center area CA and a first conductive bump 120 disposed in the outer area OA.

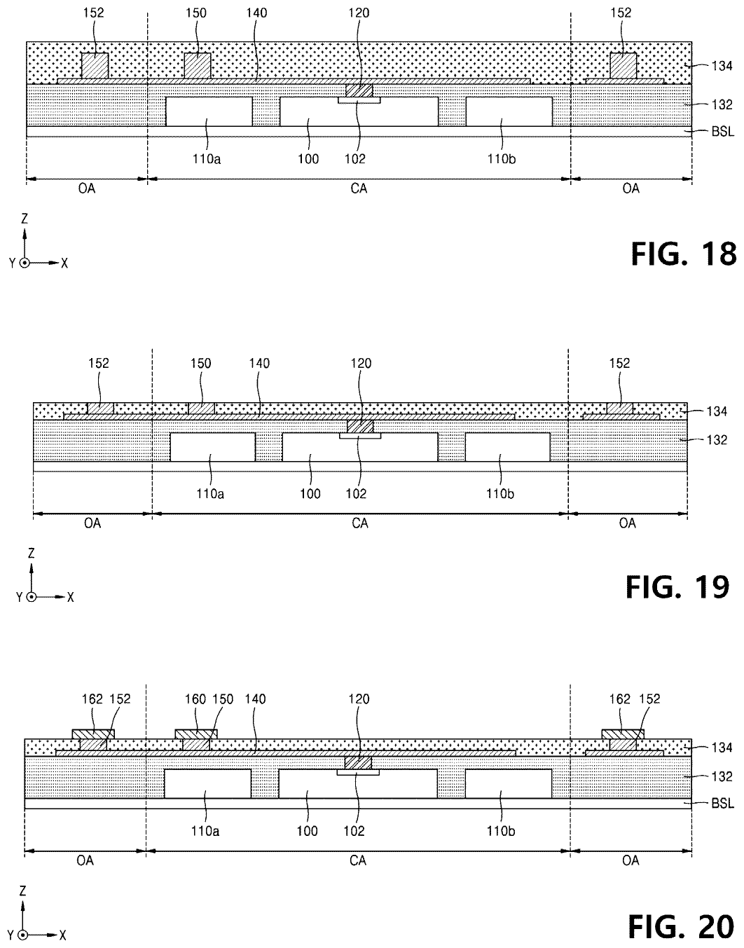

Referring to FIG. 18, the method for manufacturing a semiconductor package according to this embodiment may include forming a second insulating layer 134 on the redistribution layer 140 and the plurality of first conductive bumps 120. The second insulating layer 134 may completely embed the redistribution layer 140 and the plurality of first conductive bumps 120. The side surface of the second insulating layer 134 may be formed to be the same plane as the side surface of the first insulating layer 132.

In this case, the second insulating layer 134 may be formed of a material having a lower modulus than the first insulating layer 132.

Referring to FIG. 19, the method for manufacturing a semiconductor package according to this embodiment may include removing a portion of the second insulating layer 134 and the plurality of first conductive bumps 120 by grinding them. By grinding the second insulating layer 134 and the plurality of first conductive bumps 120, the upper surface of the second insulating layer 134 and the upper surface of each of the plurality of first conductive bumps 120 may be located on the same plane.

Referring to FIG. 20, the method for manufacturing a semiconductor package according to this embodiment may include forming a conductive pad 160 and an alignment pad 162 on the plurality of first conductive bumps 120. The alignment pad 162 may be formed through a photoresist patterning process and plating process. In this case, the conductive pad 160 may be disposed in the center area CA and the alignment pad 162 may be disposed in the outer area OA. The conductive pad 160 may be formed to be in contact with the first conductive bump 120 disposed in the center area CA and the alignment pad 162 may be formed to be in contact with the first conductive bump 120 disposed in the outer area OA.

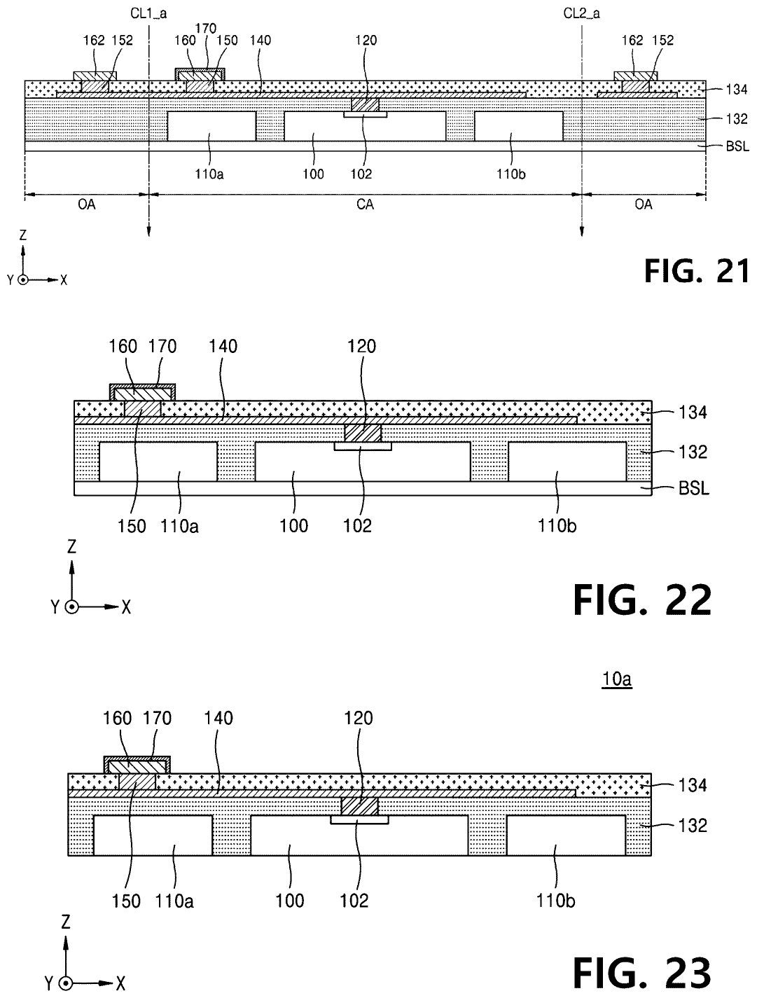

Referring to FIGS. 21 and 22, the method for manufacturing a semiconductor package according to this embodiment may include forming a cover layer 170 on the conductive pad 160 disposed in the center area CA and removing the outer area OA. The cover layer 170 may be formed using an electroless plating method or a sputtering method, and may be formed to cover at least a portion of the surface of the conductive pad 160. In addition, the method for manufacturing the semiconductor package according to an embodiment of the present disclosure may include forming the cover layer on the alignment pad 162 and then removing the outer area OA. In this case, the outer area OA may be removed based on a first cut line CL1_a and a second cut line CL2_a, which are boundaries of the section dividing the outer area OA and the center area CA.

Referring to FIG. 23, the method for manufacturing a semiconductor package according to the present embodiment may include removing the backside insulating film BSL attached on the lower surface of the semiconductor chip 100 and the lower surface of the pair of dummy chips 110a and 110b. After the backside insulating film BSL attached on the lower surface of the semiconductor chip 100 and the lower surface of the pair of dummy chips 110a and 110b is removed, the semiconductor package 10a may be completed. However, according to the embodiment, the backside insulating film BSL may not be removed.

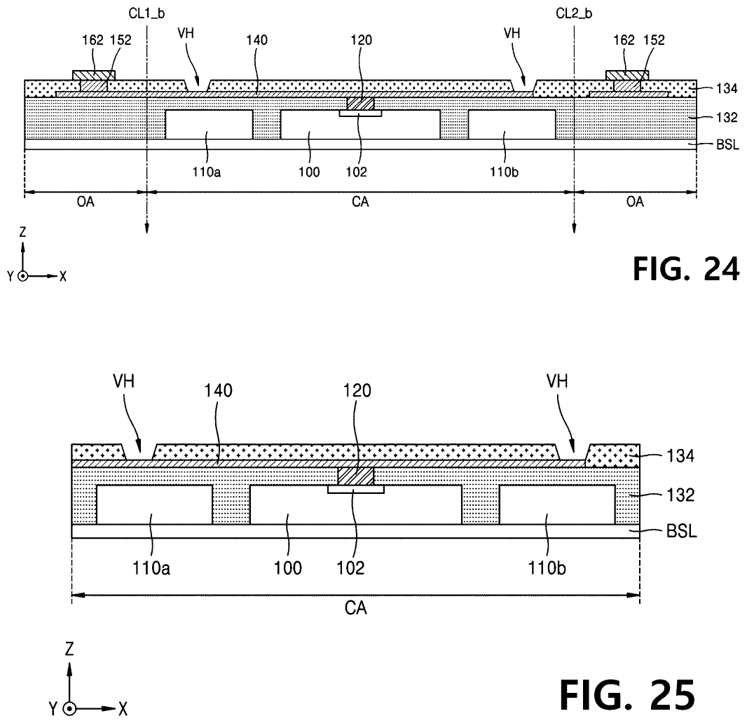

Meanwhile, according to the second embodiment of the method for manufacturing a semiconductor package according to the present disclosure, as illustrated in FIG. 24, after forming the conductive pad 160 and the alignment pad 162 on the first conductive bumps 120, as illustrated in FIG. 24, the second insulating layer 134 may be etched to form the opening VH.

In this case, the plurality of openings VH may be formed in the center area CA of the second insulating layer 134. In this case, the opening VH may be formed using the upper surface of the redistribution layer 140 embedded in the second insulating layer 134 as a limit. The opening VH may be formed using an etching process, and the opening VH may be a tapered shape in which the diameter is narrower as it becomes closer to the redistribution layer 140. In this case, the opening VH may be formed by removing the second insulating layer 134 using a laser.

Referring to FIGS. 24 and 25, the method for manufacturing a semiconductor package according to the present embodiment may include removing the outer area OA. In this case, the outer area OA may be removed based on a first cut line CL1_b and a second cut line CL2_b, which are boundaries of the section dividing the outer area OA and the center area CA. However, according to the embodiment, as illustrated in FIG. 27, after an external connection terminal 380 filling the opening VH is attached, the outer area OA may be removed.

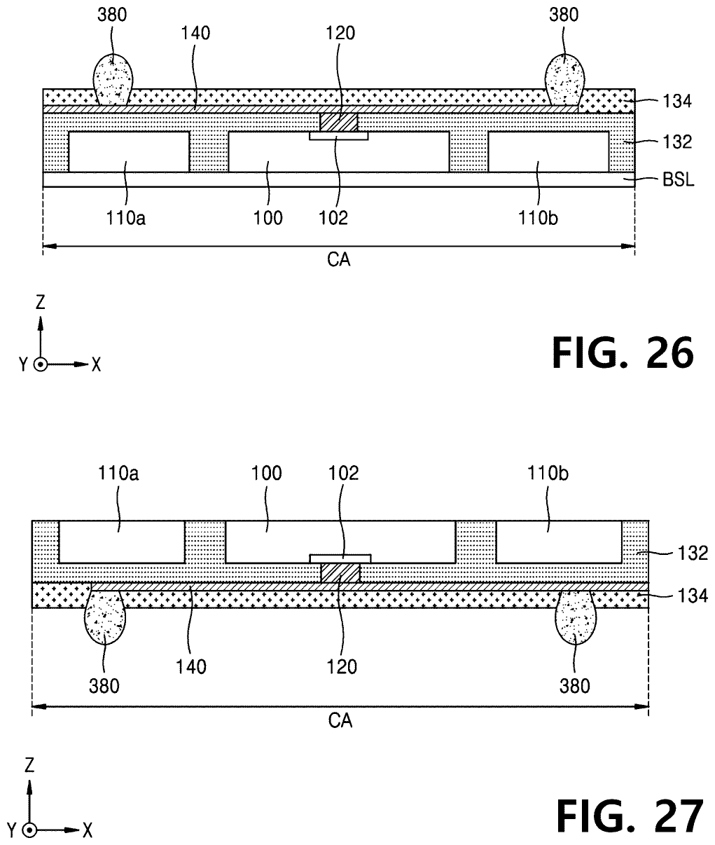

Referring to FIGS. 26 and 27, the method for manufacturing a semiconductor package according to the present embodiment may include attaching the external connection terminal 240 filling the opening VH. In this case, the external connection terminal 380 may be attached to be in contact with the redistribution layer 140. After attaching the redistribution layer 140, when the backside insulating film BSL disposed on the lower surface of the semiconductor chip 100 is removed, the semiconductor package 30a according to this embodiment is completed.

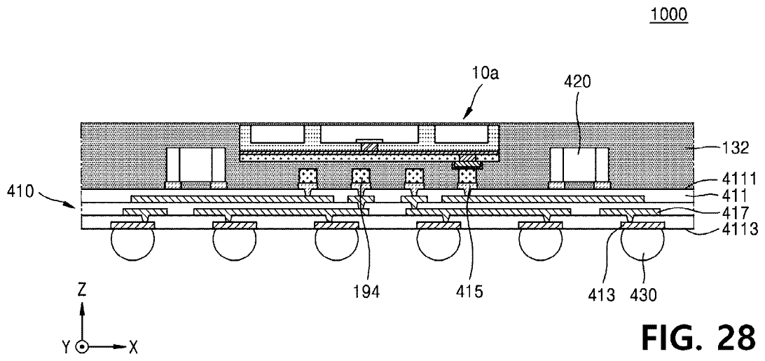

FIG. 28 is a cross-sectional view of a semiconductor package 1000 according to the seventh embodiment of the present disclosure. The semiconductor package 1000 illustrated in FIG. 28 is an embodiment in which the semiconductor package 10 illustrated in FIG. 1 is mounted on the package substrate 410. Therefore, description of the components already mentioned with reference to FIG. 1 will be omitted or simplified below.

Referring to FIG. 28, the semiconductor package 1000 may further include a package substrate 410 and a passive component 420.

The wiring insulating layer 411 may include a plurality of insulating layers stacked on each other in a vertical direction (e.g., Z direction). In FIG. 18, the wiring insulating layer 411 is illustrated to include three insulating layers, but the wiring insulating layer 411 may include two or four or more insulating layers stacked on each other in the vertical direction (e.g., Z direction). For example, the wiring insulating layer 411 may be formed of an insulating polymer, an epoxy, or a combination thereof. In exemplary embodiments, the wiring insulating layer 411 may include at least one of a photosensitive material film, polyimide, and a photo imagable dielectric PID.

The wiring insulating layer 411 may include an upper surface 4111 facing the semiconductor chip 100 and a lower surface 4113 opposite to an upper surface 4111. Hereinafter, the horizontal direction (e.g., X direction and/or Y direction) is defined as a direction (e.g., X direction and/or Y direction) parallel to the lower surface 4113 of the wiring insulating layer 411, and the vertical direction (e.g., Z direction) is defined as a direction (e.g., Z direction) perpendicular to the lower surface 4113 of the wiring insulating layer 411.

The lower pad 413 may be provided on the lower surface 4113 of the wiring insulating layer 411. The lower pad 413 may correspond to an external pad to which the external connection terminal 430 is attached. In exemplary embodiments, the lower pad 413 may be at least partially embedded in the wiring insulating layer 411, and a sidewall of the lower pad 413 may be at least partially covered by the wiring insulating layer 411. In exemplary embodiments, the sidewall of the lower pad 413 may be entirely covered by the wiring insulating layer 411.

The wiring layer 417 may extend in the vertical direction (e.g., Z direction) and/or the horizontal direction (e.g., X direction and/or Y direction) in the wiring insulating layer 411, and may be configured to electrically connect the upper pad 415 and the lower pad 413. The wiring layer 417 may have a single-layer structure or a multi-layer structure.

The upper pad 415 may be provided on the upper surface 4111 of the wiring insulating layer 411. The upper pad 415 may correspond to a pad to which the conductive connection structure is attached.

A portion of the upper pad 415 may extend on the upper surface 4111 of the wiring insulating layer 411, and another portion of the upper pad 415 may extend in the vertical direction (e.g., Z direction) in the wiring insulating layer 411 to be in contact with the wiring layer 417.

In exemplary embodiments, passive components 420 may be mounted on the package substrate 110. The passive components 420 may be spaced apart from the semiconductor chip 100 in a lateral direction. The passive components 420 may include a capacitor, an inductor, a resistor, an integrated passive device IPD, and the like.

The external connection terminal 430 may be attached to the lower pad 413 of the package substrate 110, and may electrically and physically connect the semiconductor package 1000 and an external device. For example, the external connection terminal 430 may include a solder ball or a solder bump.

A molding layer 132 may be provided on the package substrate 110, and may cover at least a portion of the semiconductor chip 100 and at least a portion of the passive components 420. In exemplary embodiments, the molding layer 132 may cover the upper surface 129 and the side surfaces of the semiconductor chip 100.

Although the embodiments of the present disclosure are described, the spirit of the present disclosure is not limited by the embodiments presented in this specification, and those skilled in the art who understand the spirit of the present disclosure may easily propose other embodiments by adding, changing, deleting, adding, etc., components within the same spirit, but this is also within the scope of the present disclosure.

### LIST OF REFERENCE SIGNS

100: semiconductor chip
110a, 110b: dummy chip
120: first conductive bump
132: first insulating layer
134: second insulating layer
140: redistribution layer
142: oxide film
150: second conductive bump
160: conductive pad
162: alignment pad
170: cover layer
380: external connection terminal

What is claimed is:

1. A package for semiconductor comprising:
a semiconductor chip;
a first insulating layer for embedding the semiconductor chip and protecting the semiconductor chip;
a redistribution layer disposed on the first insulating layer;
a second insulating layer disposed on the first insulating layer and for embedding the redistribution layer and protecting the redistribution layer; and
a conductive pad disposed on the second insulating layer.

2. The package for semiconductor of claim 1, wherein the first insulating layer and the second insulating layer form an interface.

3. The package for semiconductor of claim 1, further comprising:
a first conductive bump disposed on the semiconductor chip; and
a second conductive bump disposed on the redistribution layer.

4. The package for semiconductor of claim 3, wherein a height of the second conductive bump in a vertical direction is greater than a height of the redistribution layer in a vertical direction.

5. The package for semiconductor of claim 3, wherein the second conductive bump covers all of an upper surface and a side surface of the redistribution layer.

6. The package for semiconductor of claim 3, wherein the second conductive bump covers a portion of an upper surface of the redistribution layer and is spaced apart from a side surface of the redistribution layer.

7. The package for semiconductor of claim 1, wherein the redistribution layer overlaps with the semiconductor chip in a vertical direction.

8. The package for semiconductor of claim 1, further comprising:
an oxide film disposed on a side surface of the redistribution layer.

9. The package for semiconductor of claim 8, wherein an upper surface of the oxide film is in contact with the second insulating layer,
a lower surface of the oxide film is in contact with the first insulating layer, and
a side surface of the oxide film is in contact with the redistribution layer.

10. The package for semiconductor of claim 8, wherein a lateral length of the oxide film is shorter than a lateral length of the redistribution layer.

11. The package for semiconductor of claim 3, wherein an opening is formed in the second insulating layer,
further comprising:
an external connection terminal connected to the redistribution layer through the opening of the second insulating layer,
wherein a side surface of the redistribution layer is exposed to the outside of the second insulating layer, and
a side surface of the redistribution layer is located on the same plane as a side surface of the second insulating layer.

12. The package for semiconductor of claim 11, wherein an upper surface of the redistribution layer is in contact with the first conductive bump, and
a lower surface of the redistribution layer is in contact with the external connection terminal.

13. The package for semiconductor of claim 1, wherein a lateral length of the redistribution layer is greater than a lateral length of the semiconductor chip.

14. The package for semiconductor of claim 2, wherein an upper surface of the redistribution layer is located on the same plane as the interface.

15. The package for semiconductor of claim 1, wherein the redistribution layer overlaps with the semiconductor chip in a vertical direction.

16. The package for semiconductor of claim 1, wherein an opening is formed in the second insulating layer,
further comprising:
an external connection terminal connected to the redistribution layer through the opening of the second insulating layer; and
an oxide film disposed on the side surface of the redistribution layer,
wherein a first side surface of the oxide film is exposed to the outside of the second insulating layer,
and the first side surface of the oxide film is located on the same plane as a side surface of the second insulating layer.

17. The package for semiconductor of claim 1, wherein the modulus of the first insulating layer and the second insulating layer are different materials.

18. The package for semiconductor of claim 17, wherein the modulus of the second insulating layer is 60% or less in a room temperature condition and 30% or less in high temperature condition compared to the modulus of the first insulating layer.

19. The package for semiconductor of claim 17, wherein a flexural strength of the second insulating layer is 60% or less in room temperature condition compared to a flexural strength of the first insulating layer.

20. The package for semiconductor of claim 16, further comprising:
a conductive pad exposed on one surface of the second insulating layer and electrically connected to the redistribution layer; and
a conductive bump disposed on the semiconductor chip,
wherein the other surface of the redistribution layer is in contact with the conductive bump, and
one surface of the redistribution layer is in contact with the conductive pad.
